(19) United States
(12) Patent Application Publication
(10) Pub. No.: US 2024/0395921 A1
(43) Pub. Date: Nov. 28, 2024

(54) SEMICONDUCTOR HETEROSTRUCTURES WITH SCANDIUM III-NITRIDE LAYER

(71) Applicant: The Regents of the University of Michigan, Ann Arbor, MI (US)

(72) Inventors: Zetian Mi, Ann Arbor, MI (US); Ping Wang, Ann Arbor, MI (US); Ding Wang, Ann Arbor, MI (US); Elaheh Ahmadi, Ann Arbor, MI (US)

(21) Appl. No.: 18/686,234

(22) PCT Filed: Aug. 24, 2022
(86) PCT No.: PCT/US2022/041325

§ 371 Date: Feb. 23, 2024

(51) Int. Cl. H01L 29/778; H01L 29/20; H01L 29/66

(52) U.S. Cl. CPC H01L 29/7786; H01L 29/2003; H01L 29/66462

(57) ABSTRACT

A device includes a substrate and a semiconductor heterostructure supported by the substrate. The semiconductor heterostructure includes a first semiconductor layer supported by the substrate and including a first III-nitride semiconductor material, and a second semiconductor layer supported by the first semiconductor layer and including a second III-nitride semiconductor material. The second III-nitride semiconductor material includes scandium. The first and second semiconductor layers are nitrogen-polar.

### CROSS-REFERENCE TO RELATED APPLICATION

This application claims the benefit of U.S. provisional application entitled “Semiconductor Heterostructures With Scandium Ill-Nitride Layer,” filed Aug. 24, 2021, and assigned Ser. No. 63/236,500, the entire disclosure of which is hereby expressly incorporated by reference . . . .

### STATEMENT REGARDING FEDERALLY SPONSORED RESEARCH OR DEVELOPMENT

This invention was made with government support under Contract No. N00014-19-1-2225 awarded by the Naval Research Office. The government has certain rights in the invention.

### BACKGROUND OF THE DISCLOSURE

### Field of the Disclosure

The disclosure relates generally to III-nitride semiconductor heterostructures.

### Brief Description of Related Technology

Alloying aluminum nitride (AlN) with the rare-earth metal scandium (Sc) to form ultra-wide bandgap semiconductor ScₓAl₁₋ₓN in the wurtzite phase has recently drawn tremendous attention due to a significantly enhanced piezoelectric response, unique ferroelectric behavior, and dramatically increased spontaneous polarization. These attractive properties enable prospective applications in micro-electromechanical systems (MEMS), high-frequency acoustic resonators and filters, and ferroelectric field-effect transistors (Fe-FET). Significantly, the ferroelectric polarization switching of ScₓAl₁₋ₓN provides distinct opportunities for the integration of ferroelectric functionality into III-nitride electronics, and further enriches the dimension of polarization engineering in nitride semiconductors. In this context, molecular beam epitaxy (MBE) and metal-organic vapor deposition (MOCVD) have been successfully employed for the epitaxy of high-quality ScₓAl₁₋ₓN on SiC and GaN/AlN templates, which enable seamless integration of ferroelectric functionality with III-N device technology.

Recent progress of gallium nitride (GaN)-based high electron mobility transistors (HEMTs) has enabled state of the art high power density radio-frequency (RF) devices.

Analogous to AlGaN and InAlN, ScₓAl₁₋ₓN is a promising barrier layer in GaN-based HEMTs, but offers a larger spontaneous polarization. Lattice matched metal-polar ScₓAl₁₋ₓN/GaN HEMTs with high sheet electron concentration (about 3×10¹³ cm⁻²) and high electron mobility (about 1000 cm²/V·s) have been reported using MBE and MOCVD, suggesting the capability of obtaining high-power and high-frequency performance. For applications in millimeter- and sub-millimeter-wave frequencies, however, metal-polar ScₓAl₁₋ₓN/GaN HEMTs will meet the same scaling challenges as conventional GaN HEMTs.

### SUMMARY OF THE DISCLOSURE

In accordance with one aspect of the disclosure, a device includes a substrate and a semiconductor heterostructure supported by the substrate. The semiconductor heterostructure includes a first semiconductor layer supported by the substrate and including a first III-nitride semiconductor material, and a second semiconductor layer supported by the first semiconductor layer and including a second III-nitride semiconductor material. The second III-nitride semiconductor material includes scandium. The first and second semiconductor layers are nitrogen-polar.

In accordance with another aspect of the disclosure, a transistor device includes a substrate, a buffer layer supported by the substrate and including a first III-nitride semiconductor material, a barrier layer supported by the buffer layer and including a second Ill-nitride semiconductor material, and a channel layer supported by the barrier layer and including a compound semiconductor material. The second Ill-nitride semiconductor material includes scandium. The buffer and barrier layers are nitrogen-polar.

In accordance with yet another aspect of the disclosure, a transistor device includes a substrate, a buffer layer supported by the substrate and including a first III-nitride semiconductor material, a barrier layer supported by the buffer layer and including a second Ill-nitride semiconductor material, and a channel layer supported by the barrier layer and including a compound semiconductor material. The second III-nitride semiconductor material includes scandium. The first III-nitride semiconductor material and the second III-nitride semiconductor material are lattice mismatched.

In accordance with still another aspect of the disclosure, a method of fabricating a heterostructure includes growing epitaxially a first semiconductor layer of the heterostructure, the first semiconductor layer including a first Ill-nitride semiconductor material, the first III-nitride semiconductor material being supported by a substrate, and after growing the first semiconductor layer, growing epitaxially a second semiconductor layer of the heterostructure such that the second semiconductor layer is supported by the first semiconductor layer, the second semiconductor layer including a second III-nitride semiconductor material. The second III-nitride semiconductor material includes scandium. The first and second semiconductor layers are nitrogen-polar.

In connection with any one of the aforementioned aspects, the devices and/or methods described herein may alternatively or additionally include or involve any combination of one or more of the following aspects or features. The first semiconductor layer includes gallium nitride (GaN). The second semiconductor layer includes scandium aluminum nitride (ScₓAl₁₋ₓN). The first semiconductor is in contact with the substrate. The second semiconductor layer is in contact with the first semiconductor layer. The device further includes a third semiconductor layer disposed between the first and second semiconductor layers. The third semiconductor layer includes a third III-nitride semiconductor material differing from the first Ill-nitride semiconductor material. The third semiconductor layer includes aluminum nitride (AlN). The first and second semiconductor layers are lattice matched. The first and second semiconductor layers are lattice mismatched. The first Ill-nitride semiconductor material and the second III-nitride semiconductor material are lattice mismatched. The compound semiconductor material includes the first III-nitride semiconductor material. The buffer layer includes gallium nitride (GaN). The barrier layer includes scandium aluminum nitride (ScₓAl₁₋ₓN). The buffer layer is in contact with the substrate. The transistor device further includes a further semiconductor layer disposed between the buffer and barrier layers. The further semiconductor layer includes a third Ill-nitride semiconductor material differing from the first III-nitride semiconductor material. The further semiconductor layer includes aluminum nitride (AlN). Growing epitaxially the second semiconductor layer is implemented under nitrogen-rich conditions. Growing epitaxially the second semiconductor layer is implemented at a growth temperature falling in a range from about 600 degrees Celsius to about 900 degrees Celsius.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts graphical plots of x-ray diffraction rocking curve (XRC) and other x-ray diffraction data for nitrogen-polar ScₓAl₁₋ₓN layers in accordance with a number of examples, along with graphical plots of reciprocal space mapping (RSM) data for nitrogen-polar ScₓAl₁₋ₓN layers in accordance with a number of examples.

FIG. 2 depicts atomic force microscope (AFM) images of nitrogen-polar ScₓAl₁₋ₓN layers in accordance with a number of examples, along with an inset image of a titled-view, scanning electron microscope (SEM) image of a nitrogen-polar ScₓAl₁₋ₓN layer in accordance with one example.

FIG. 3 depicts a schematic view of a device having a semiconductor heterostructure with a nitrogen-polar Ill-nitride semiconductor material that includes scandium in accordance with one example, as well as an AFM image of a semiconductor heterostructure with a nitrogen-polar Ill-nitride semiconductor material that includes scandium in accordance with one example, and graphical plots of corresponding electron density and sheet electron concentration.

FIG. 4 is a flow diagram of a method of fabricating a heterostructure with a nitrogen-polar Ill-nitride semiconductor material that includes scandium in accordance with one example.

FIG. 5 is a schematic view of a transistor device having a semiconductor heterostructure with a nitrogen-polar Ill-nitride semiconductor material that includes scandium in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Transistor and other devices with heterostructures having a scandium III-nitride semiconductor layer are described. The scandium III-nitride semiconductor layer may be nitrogen polar (N-polar). In some cases, the devices are configured as HEMT devices. N-polar GaN HEMTs offer intrinsic scaling advantages for high-frequency transistors due to the inherent back barrier, enhanced two-dimensional electron gas (2DEG) confinement, and inverted polarization. Using ScₓAl₁₋ₓN as the barrier in N-polar GaN HEMTs may be beneficial to further improve the operating frequency while maintaining high output power.

Methods for fabricating such devices through epitaxial growth of the scandium III-nitride semiconductor layer are also described. For instance, molecular beam epitaxy (MBE) may be used.

Described herein are examples of the epitaxy of N-polar ScₓAl₁₋ₓN with varying Sc content (x) on sapphire substrates using plasma-assisted MBE. The residual strain of ScₓAl₁₋ₓN films is described using x-ray diffraction reciprocal space mapping (XRD RSM), which confirmed the coherent growth of lattice-matched Sc_{0.18}Al_{0.82}N on GaN. Examples involving Sc_{0.11}Al_{0.89}N and Sc_{0.30}Al_{0.70}N that are lattice mismatched to GaN are also described. The examples exhibited crack-free surfaces and were almost fully relaxed. The N-polar orientation was confirmed by wet chemical etching. Electrical properties of the grown N-polar HEMTs using Sc_{0.18}Al_{0.82}N as a barrier on sapphire substrates are also described. Hall mobility up to 564 cm²V·s was measured with a sheet electron concentration of 4.1×10¹³ cm-2. The resulting sheet resistance is as low as 271 Ω/sq.

Although described in connection with HEMT devices, the disclosed methods and devices may be applied to a wide variety of electronic and other devices. For instance, the disclosed devices may be non-electronic devices, such as photonic, acoustic, and piezoelectric devices.

Although described in connection with examples having a ScₓAl₁₋ₓN layer, the disclosed methods and devices are also useful in connection with other scandium Ill-nitride semiconductor materials. For instance, scandium III-nitride semiconductor materials, such as ScAlN, ScGaN, ScAlGaN, ScInN, and their alloys, may be used.

Although described in connection with N-polar layers and devices, one or more layers of the disclosed devices may be metal-polar. For instance, the disclosed methods may be configured to fabricate a scandium III-nitride semiconductor layer, whether N-polar or metal-polar, having a scandium content in a range for lattice mismatch (e.g., with a GaN layer). Such lattice mismatch may be useful in connection with improvements to the polarization field, barrier height, and strain distribution. These and other parameters may be controlled or addressed by varying the Sc composition.

The examples of N-polar ScₓAl₁₋ₓN films were grown utilizing a Veeco GENxplor MBE system, equipped with a RF plasma source, a high-temperature Knudsen cell for a Sc source, and dual-filament SUMO Knudsen cells for Al and Ga sources. ScₓAl₁₋ₓN films were grown on 700-nm-thick N-polar GaN templates, which were grown using the same MBE system on sapphire (0001) substrates. A N₂ flow rate of 0.3 sccm (standard cubic centimeters per minute) with an RF power of 350 W was used throughout the growth, corresponding to a growth rate of about 240 nm/h for GaN films. The example ScₓAl₁₋ₓN films were grown under nitrogen (N)-rich conditions, which are useful to improve phase purity and surface roughness. Sc content was controlled by proportionally tuning the Sc/Al beam equivalent pressure (BEP) ratio while maintaining a total BEP of 7.0×10⁻⁸ Torr for the sum of Sc+Al, corresponding to a III/V BEP ratio of about 0.82. Growth temperature (T_{G}) was varied in the range of about 600 to about 900 degrees Celsius (C), which was monitored with a thermocouple located on the backside of the substrate. The thermocouple readings were calibrated on the (7×7) to (1×1) reconstruction transition of Si(111) at about 830 degrees C.

The growth process was in situ monitored using reflection high energy electron diffraction (RHEED). The surface roughness was characterized using a Bruker ICON atomic force microscope (AFM). Sc content was determined utilizing energy dispersive x-ray spectroscopy (EDS) equipped on a Hitachi SU8000 scanning electron microscope (SEM). XRD was performed using a Rigaku SmartLab and Bruker D8 diffractometers with a Cu Kα1 radiation X-ray source (1.5406 Å). Electrical properties were analyzed by a Ecopia HMS-3000 Hall measurement system, with four indium solder dot Ohmic contacts placed near the corners of 5×5 mm² samples in van der Pauw geometry.

Two series of samples were studied to explore the epitaxy and characteristics of N-polar ScₓAl₁₋ₓN: (i) Sc_{0.18}Al_{0.82}N deposited at T_{G} in a range from about 600 to about 900 degrees C., and (ii) ScₓAl₁₋ₓN with varying Sc content (x from about 0.11 to about 0.47) deposited at T_{G} of about 700 degrees C. A list of ScₓAl₁₋ₓN example films is shown below in Table I. The thicknesses of the ScₓAl₁₋ₓN films were measured in the range of about 90 to about 110 nm with decreasing Sc content, corresponding to a slowly increasing growth rate. All Sc_{0.18}Al_{0.82}N samples grown with varying T_{G} have a wurtzite structure, which was confirmed by the RHEED patterns and (002) plane XRD 2θ-ω scans.

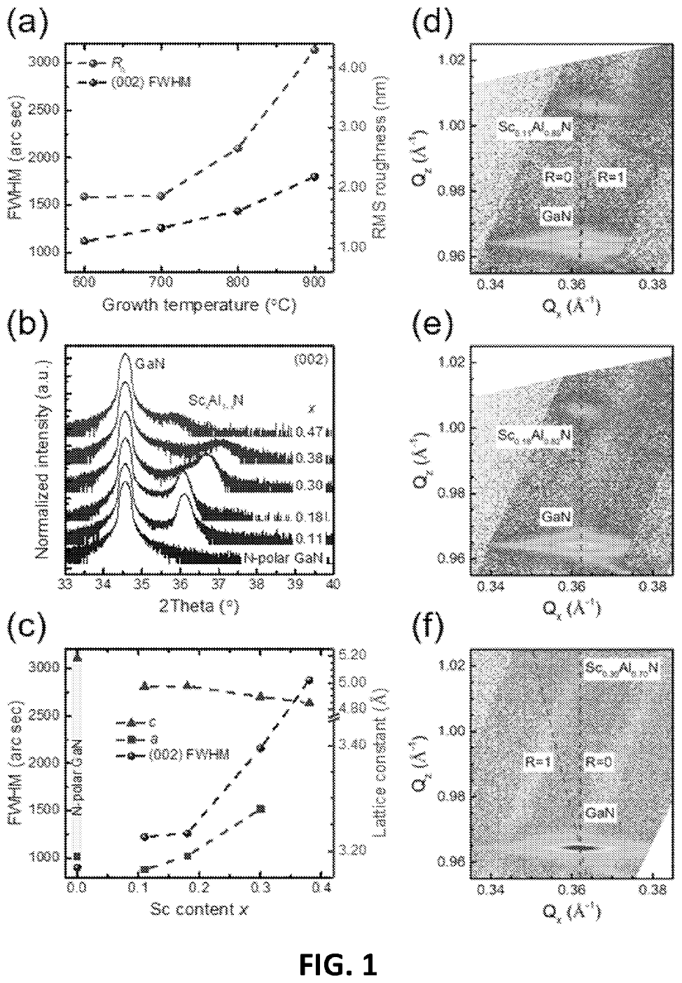

With reference to part (a) of FIG. 1, the full-width at half-maximum (FWHM) of (002) plane XRD rocking curve (XRC) for Sc_{0.18}Al_{0.82}N increases gradually with increasing T_{G}, while the root mean square (RMS) roughness (Rq) acquired from a 3×3 μm² scan area degrades more severely, which are in agreement with previous reports on metal-polar ScₓAl₁₋ₓN. Considering the incorporation of impurities with decreasing growth temperature, a T_{G} of about 700 degrees C. was chosen for the growth of several examples of ScₓAl₁₋ₓN with varying Sc content.

Table I depicts growth conditions (T_{G} and III/V BEP ratio), Sc content (x), and surface RMS roughness for a number of example films.

TABLE I
Growth conditions (T_{G} and III/V BEP ratio),
Sc content (x), and surface RMS roughness (R_{q})
(scan area 3 × 3 μm²) of N-polar ScₓAl₁₋ₓN samples.

| Sample | T_{G} | III/V BEP ratio | | R_{q} |
|---|---|---|---|---|
| No. | (° C.) | (Sc + Al)/N* | x | (nm) |
| S0 | 800 | GaN | — | 1.40 |
| S1 | 600 | 0.82 | 0.18 | 1.85 |
| S2 | 700 | 0.82 | 0.18 | 1.86 |
| S3 | 800 | 0.82 | 0.18 | 2.66 |
| S4 | 900 | 0.82 | 0.18 | 4.30 |
| S5 | 700 | 0.82 | 0.11 | 1.59 |
| S6 | 700 | 0.82 | 0.30 | 1.18 |
| S7 | 700 | 0.82 | 0.38 | 1.13 |
| S8 | 700 | 0.82 | 0.47 | 2.38 |

FIG. 1 depicts, in part (a), the (002) plane XRC FWHM and RMS roughness of N-polar Sc_{0.18}Al_{0.82}N versus growth temperature, in part (b) (002) plane XRD 2θ-ω scans, and in part (c), (002) plane XRC FWHM and lattice parameters of N-polar ScₓAl₁₋ₓN with varying Sc content (x of about 0.11 to about 0.47). The corresponding parameters for N-polar GaN template are also plotted in part (c) for comparison. Parts (d-f) of FIG. 1 depict the asymmetric (105) plane RSM images of N-polar Sc_{0.11}Al_{0.89}N, Sc_{0.18}Al_{0.52}N, and Sc_{0.30}Al_{0.70}N examples grown at 700 degrees C. The fully relaxed/strained positions (R=1/0) are depicted as dashed lines.

Described herein is the epitaxy of ScₓAl₁₋ₓN layers with varying Sc content (e.g., x of about 0.11 to about 0.47), which were grown at T_{G} of about 700 degrees C. The final RHEED patterns evolved from bright spotty into broad segments with increasing Sc content, and transformed into dashed rings for x of about 0.47, indicating the deterioration of wurtzite structure in this Sc content regime. A (002) plane XRD 2θ-ω scan for these ScₓAl₁₋ₓN samples is presented in part (b) of FIG. 1. The prominent characteristic peaks located in a 2θ range of 36.0 degrees to 37.1 degrees suggest a wurtzite phase for ScₓAl₁₋ₓN epilayers with Sc content up to 0.38, which is lower than the theoretically predicted value of 0.56. For Sc_{0.47}Al_{0.53}N, a weak diffraction peak appears at the higher angle side of GaN (002) peak, suggesting the existence of rock-salt phase ScₓAl₁₋ₓN. The phase transition starting point is in a Sc content range of 0.38-0.47, agreeing well with previous experimental results. The (002) plane diffraction peak of ScₓAl₁₋ₓN gradually broadens and shifts toward higher angle side with increasing Sc content (x≥0.20), indicating a decrease in the out-of-plane lattice parameter c, which is coincident with the trend for metal-polar ScₓAl₁₋ₓN. Meanwhile, the residual strain may also contribute somewhat to the shift of diffraction peaks. The FWHM of (002) plane XRC data for these ScₓAl₁₋ₓN samples is shown in part (c) of FIG. 1 (circular data points). A reasonably good crystal quality (FWHM<1500 arcsec) was achieved for lower Sc content (x≤0.20), while higher Sc content (x>0.20) results in degradation of the crystal quality, but are significantly better than the several degrees of FWHM previously reported for sputter deposited ScₓAl₁₋ₓN. The crystal quality of ScₓAl₁₋ₓN can be further improved by using a high quality N-polar GaN template or free-standing N-polar GaN.

Parts (d)-(f) of FIG. 1 illustrate the XRD RSM for the asymmetric (105) plane of Sc_{0.11}Al_{0.89}N, Sc_{0.18}Al_{0.82}N, and Sc_{0.30}Al_{0.70}N, respectively, grown at 700 degrees C. The fully relaxed/strained positions (R=1/0) acquired from the theoretical predicted lattice parameters are indicated by dashed lines. Shown in part (e) of FIG. 1, the RSM of Sc_{0.18}Al_{0.82}N indicates coherent strain, as the in-plane reciprocal lattice unit Qₓ shares the same value between the N-polar GaN template and the Sc_{0.18}Al_{0.82}N epilayer, whereas Sc_{0.11}Al_{0.38}N and Sc_{0.30}Al_{0.70}N are almost fully relaxed (parts (d) and (f) of FIG. 1). From the respective Qₓ and Q_{z} values, the lattice parameters obtained for Sc_{0.18}Al_{0.82}N are a=3.19 Å and c=4.98 Å, consistent with previous reports. Part (c) of FIG. 1 plots the lattice parameters a (squares, in-plane) and c (triangles, out-of-plane) calculated from RSM. The c/a ratio of ScₓAl₁₋ₓN decreases significantly from 1.57 (Sc_{0.11}Al_{0.89}N) to 1.49 (Sc_{0.30}Al_{0.70}N) relative to AlN (about 1.60) with an increasing Sc content, which agrees well with previous studies.

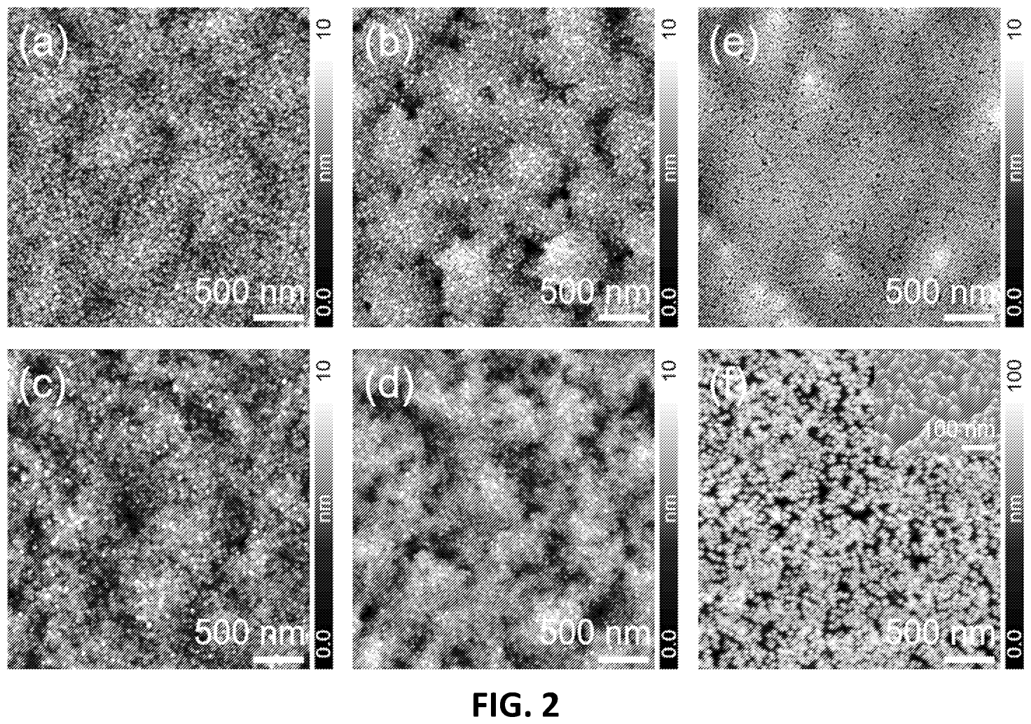

FIG. 2 depicts 3×3 μm² AFM images of N-polar ScₓAl₁₋ₓN grown at 700 degrees C. with varying Sc content, namely part (a)—Sc_{0.11}Al_{0.89}N(R_{q}=1.59 nm), part (b)—Sc_{0.18}Al_{0.82}N(R_{q}=1.86 nm), part (c)—Sc_{0.30}Al_{0.70}N(R_{q}=1.18 nm), and part (d)—Sc_{0.38}Al_{0.62}N (R_{q}=1.13 nm). Parts (e) and (f) of FIG. 2 depict 3×3 μm² AFM images of Sc_{0.18}Al_{0.82}N after TMAH (20 wt. %) etching at 50 degrees C. for 5 min, with part (e) being metal-polar (R_{q}=1.05 nm) and part (f) being N-polar (R_{q}=14.3 nm). The inset of part (f) shows the corresponding tilted-view SEM image.

Parts (a)-(d) of FIG. 2 show the surface morphology of ScₓAl₁₋ₓN with varying Sc content. Instead of the hillocks that appeared in metal-polar ScₓAl₁₋ₓN, island-like morphology was observed in parts (a)-(d) of FIG. 2 due to the imprint effect of the underlying N-polar GaN template. The RMS roughness acquired from a 3×3 μm² scan area is less than 2.0 nm, which is largely limited by the underlying N-polar GaN template. The RMS roughness of the same scan area for MBE grown N-polar GaN template was about 1.41 nm. All of the examples have a granular surface, which is similar to previous reports on ScₓAl₁₋ₓN grown on metal-polar GaN/AlN templates. Corresponding SEM images for the examples shown in FIG. 2 did not reveal clear secondary grain or metal dendritic growths. In contrast to the metal-polar ScₓAl₁₋ₓN grown in the similar temperature regime, especially for higher Sc content, no surface cracks were observed in the entire Sc content range for N-polar ScₓAl₁₋ₓN, which is mainly due to the efficient relaxation of strain.

To verify the lattice-polarity, two Sc_{0.18}Al_{0.82}N samples grown on Ga-polar and N-polar GaN/sapphire templates, respectively, were etched in TMAH solution (20 wt %) at 50 degrees C. for 5 min. The corresponding AFM images are shown in parts (e) and (f) of FIG. 2. The surface morphology of metal-polar Sc_{0.18}Al_{0.82}N barely changes after etching (R_{q}=1.05 nm, FIG. 2, part(e)). However, the Sc_{0.18}Al_{0.82}N grown on an N-polar GaN template can be readily etched. The RMS roughness deteriorated from 1.86 nm (before etching) to 14.35 nm (after etching), and hexagonal pyramids can be easily observed on the surface, as shown in part (f) of FIG. 2 and the inset. These phenomena suggest a well epitaxial registry and lattice continuity for a ScₓAl₁₋ₓN epilayer grown on an N-polar GaN template. That is, these ScₓAl₁₋ₓN layers possess on-axis N-polarity.

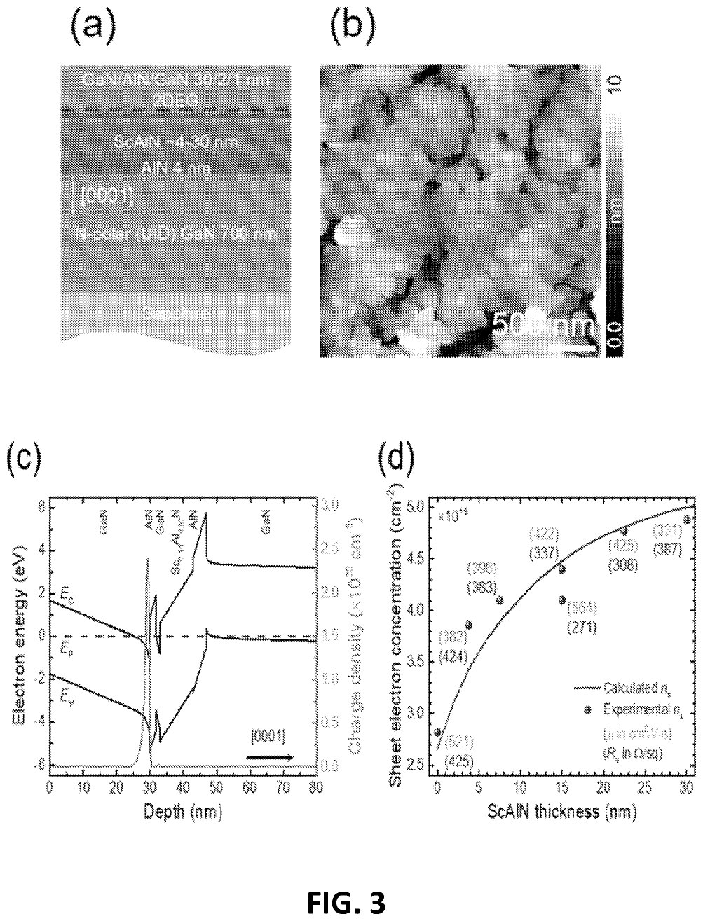

With reference now to FIG. 3, part (a) depicts a schematic view of a heterostructure having a Sc_{0.18}Al_{0.82}N barrier layer. In some cases, the heterostructure may be configured as a HEMT structure. The location of the 2DEG is shown by a dashed line. Part (b) of FIG. 3 depicts a 3×3 μm² AFM image of a N-polar Sc_{0.18}Al_{0.82}N HEMT structure (R_{q}=1.60 nm). Part (c) of FIG. 3 depicts a band diagram of the structure shown in part (a) with a 10-nm-thick Sc_{0.18}Al_{0.82}N barrier. Part (d) of FIG. 3 depicts the sheet electron concentration (nₛ) for HEMT devices with varying Sc_{0.18}Al_{0.82}N barrier thicknesses. Simulated results and experimental data are plotted as a curve and circular points, respectively. Mobility (μ) and sheet resistance (Rₛ) for each sample are labeled next to the corresponding nₛ data point.

To demonstrate the usefulness of N-polar ScₓAl₁₋ₓN in electronic device applications, example Sc_{0.18}Al_{0.82}N/GaN HEMT devices with an epi-structure shown in part (a) of FIG. 3 were grown on sapphire substrates. In these examples, a 700-nm-thick unintentionally doped (UID) GaN buffer layer was first deposited on sapphire, followed by a 4-nm-thick AlN electron blocking layer (EBL) to help screen the contribution of the residual electron concentration in N-polar GaN buffer by providing an additional large barrier to avoid parallel conduction channel formation as much as possible. This AlN EBL is not necessary if, for instance, a semi-insulating N-polar GaN is employed as a buffer layer. Subsequently, Sc_{0.18}Al_{0.82}N with varying thicknesses from 4 to 30 nm were grown as a barrier layer, and 1-nm-thick GaN and 2-nm-thick AlN layers were used to improve the surface morphology and reduce the interface roughness scattering. Finally, 30-nm-thick GaN was grown as a channel layer. Part (b) of FIG. 3 shows a representative AFM image of N-polar HEMTs using Sc_{0.18}Al_{0.82}N as a barrier. The corresponding RMS roughness is about 1.60 nm.

The band diagram and sheet electron density of these example N-polar Sc_{0.18}Al_{0.82}N/GaN HEMT devices were simulated using a coupled one-dimensional Poisson-Schrödinger solver embedded in the Silvaco-ATLAS numerical simulation platform. The band diagram of Sc_{0.18}Al_{0.82}N/GaN HEMT structure with a 10-nm-thick Sc_{0.18}Al_{0.82}N barrier is illustrated in part (c) of FIG. 3. A highly localized 2DEG is formed in the GaN channel layer (green curve). The sheet electron concentration with varying barrier thicknesses is plotted in part (d) of FIG. 3. The sheet electron concentration (nₛ), electron mobility (μ), and corresponding sheet resistance (Rₛ) for a series of N-polar HEMT devices measured via the Hall effect are shown in part (d) of FIG. 3. The charge density varies between 3.86×10¹³ and 4.88×10¹³ cm⁻² with increasing barrier thickness from 4 to 30 nm. The highest mobility achieved is 564 cm²/V·s for the 15-nm-thick Sc_{0.18}Al_{0.82}N barrier sample with nₛ=4.1×10¹³ cm⁻², and the corresponding sheet resistance is as low as 271 Ω/sq. Overall, the measured sheet electron concentrations agree well with the simulated results. The relatively low mobility is mainly due to the non-atomic smooth interface of Sc_{0.18}Al_{0.82}N. Improved smoothness may be achieved by varying the growth conditions.

Epitaxial growth of single-phase wurtzite N-polar ScₓAl₁₋ₓN with varying Sc content (x of about 0.11 to about 0.38) on sapphire substrates has been demonstrated using plasma-assisted MBE. Coherent growth of lattice-matched Sc_{0.18}Al_{0.82}N on GaN buffer has been confirmed by XRD RSM, while the inheritance of lattice-polarity from the underlying GaN buffer is evidenced by the readily etched surface of N-polar ScₓAl₁₋ₓN. N-polar HEMT devices using Sc_{0.18}Al_{0.82}N as a barrier have also been grown, showing the lowest achieved sheet resistance of 271 Ω/sq, with a sheet electron density of 4.1×10¹³ cm⁻² and a mobility of 564 cm²/V·s for a 15-nm-thick Sc_{0.18}Al_{0.82}N barrier. These examples show that N-polar ScₓAl₁₋ₓN is a useful material for high-frequency and high-power electronic devices in addition to piezoelectric and ferroelectric applications.

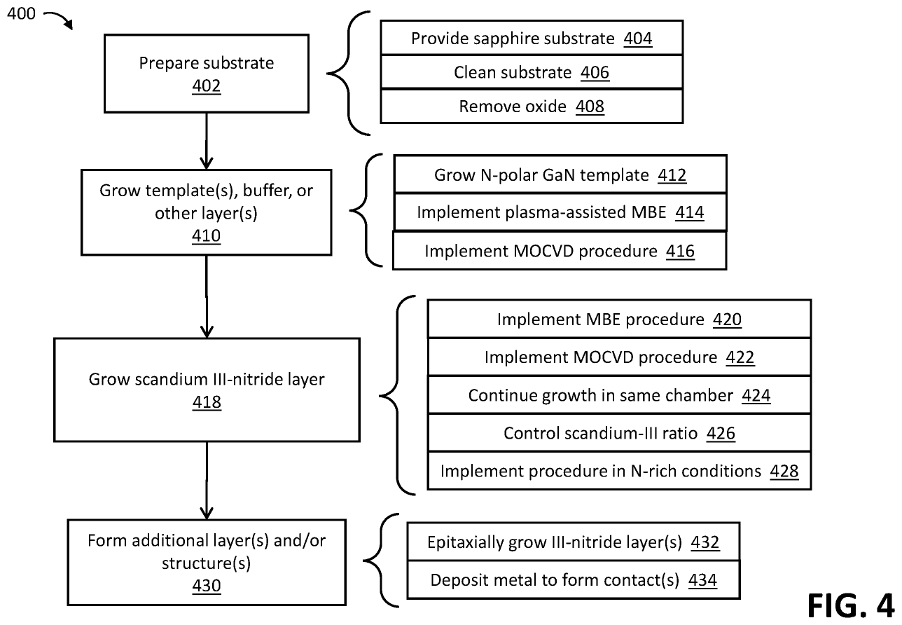

FIG. 4 depicts a method 400 of fabricating a heterostructure having a scandium Ill-nitride layer in accordance with one example. As described herein, the method 400 may be configured such that the scandium Ill-nitride layer is N-polar. The heterostructure may form a device, or a part of a device, such as a HEMT device. The method 400 may be used to fabricate the examples of ScₓAl₁₋ₓN films and layers described herein.

The method 400 may begin with an act 402 in which a substrate is prepared and/or otherwise provided. In some cases, the act 402 includes providing a sapphire substrate in an act 404. Alternative or additional materials may be used, including, for instance, silicon, bulk GaN, bulk AlN, or other semiconductor material. Still other materials may be used, including, for instance, silicon carbide. The substrate may be cleaned in an act 406. In some cases, a native or other oxide layer may be removed from a substrate surface in an act 408. Additional or alternative processing may be implemented in other cases, including, for instance, doping or deposition procedures. The substrate thus may or may not have a uniform composition. The substrate may be a uniform or composite structure.

In an act 410, one or more semiconductor growth templates or other layers are epitaxially grown. The semiconductor layer(s) are thus formed on, or otherwise supported by, the substrate. The semiconductor layer(s) may or may not be in contact with the substrate. In some cases, the semiconductor layer(s) are composed of, or otherwise include, GaN, but other III-nitride semiconductor materials may be used, including, for instance, AlN, AlGaN, and AlInN. In the example of FIG. 4, a N-polar GaN layer is grown in an act 412. In cases involving a N-polar layer, the semiconductor layer may act as a template for subsequent growth of one or more N-polar semiconductor layers.

The act 412 may thus be implemented before (e.g., in preparation for) implementing an epitaxial growth procedure in which a scandium III-nitride layer is formed. The scandium Ill-nitride layer may thus be formed on the semiconductor layer. The semiconductor layer may be configured or used as a growth template for the scandium III-nitride layer and/or other elements of the heterostructure. In some cases, the act 412 may include growing the semiconductor layer in an epitaxial growth chamber in which the epitaxial growth procedure for the scandium III-nitride layer is implemented. As a result, the substrate may remain within, e.g., is not removed from, the epitaxial growth chamber between forming the semiconductor layer and implementing the epitaxial growth procedure for growing the scandium III-nitride layer.

The act 410 may include an act 414 in which the semiconductor layer is grown via implementation of a plasma-assisted MBE procedure. Alternative or additional procedures may be used. For instance, the semiconductor layer may be grown in an act 416 via implementation of a MOCVD procedure.

The GaN template or other semiconductor layer grown in the act 410 may be grown directly on the substrate. For instance, the GaN template or other semiconductor layer is grown without an AlN buffer layer. This is in contrast to previous techniques in which the GaN template or other semiconductor layer was grown on an AlN buffer, which results in a metal-polar GaN layer. Without the AlN buffer layer, the GaN template or other semiconductor layer may be grown in a manner that results N-polarity.

After growing the semiconductor layer in the act 410, another semiconductor layer of the heterostructure is grown in an act 418 such that the semiconductor layer is supported by the semiconductor layer grown in the act 410. The semiconductor layer grown in the act 418 is composed of, or otherwise includes, a III-nitride semiconductor material that includes scandium. For instance, the scandium III-nitride semiconductor material may be ScAlN, ScGaN, ScAlGaN, ScInN, and their alloys. In some cases, the semiconductor layers formed in the acts 410 and 418 are nitrogen-polar. The N-polarity of the GaN template or other semiconductor layer grown in the act 410 allows the scandium III-nitride semiconductor material to be N-polar. Alternatively, the semiconductor layers are metal-polar, as described herein. The growth conditions may be set such that the semiconductor layers may be lattice matched or mismatched, as described herein.

The act 418 may include an act 420 in which the scandium III-nitride layer is grown via implementation of an MBE procedure. Alternatively, a MOCVD procedure is implemented in an act 422. In either case, the growth may be continued in an act 424 in which in the same chamber used in the act 410 is used to grow the scandium III-nitride layer.

The growth conditions may be controlled to establish a scandium content of the scandium III-nitride layer. For instance, the scandium-aluminum (or other Group III element) beam equivalent pressure ratio may be controlled in an act 426. In some cases, the scandium-III beam equivalent ratio is controlled such that a scandium content of the scandium III-nitride semiconductor material falls in a range from about 0.11 to about 0.38. However, the scandium content may fall outside of the range in other cases, e.g., between 0 and a theoretically predicted maximum of 0.56.

The scandium III-nitride semiconductor layer may be grown at a growth temperature falling in a range from about 600 degrees C. to about 900 degrees C. For example, the growth temperature may be about 700 degrees C. Other growth temperatures may be used in other cases, including, for instance, temperatures below 600 degrees C.

The act 418 may also include an act 428 in which the scandium Ill-nitride semiconductor layer is implemented under nitrogen-rich conditions. One or more of the other semiconductor layers of the heterostructure may also be grown under nitrogen-rich conditions.

The method 400 may include an act 430 in which one or more additional layers or other structures are formed. In some cases, the act 430 includes growing one or more III-nitride layers in an act 432. For example, a channel layer of a HEMT device may be grown.

The act 430 may also include an act 434 in which one or more metal layers are deposited and patterned to form one or more contacts or electrodes. For example, metal may be deposited to form source, drain, and gate electrodes of an HEMT device.

The method 400 may include fewer, alternative, or additional acts. For example, the method 400 may include the implementation of one or more doping procedures for one or more of the semiconductor layers described herein. Such doping may be useful in connection with charge carrier confinement and/or other purposes. The method 400 may also include any number of additional acts directed to the growth or other formation of additional semiconductor layers, such as cap layers.

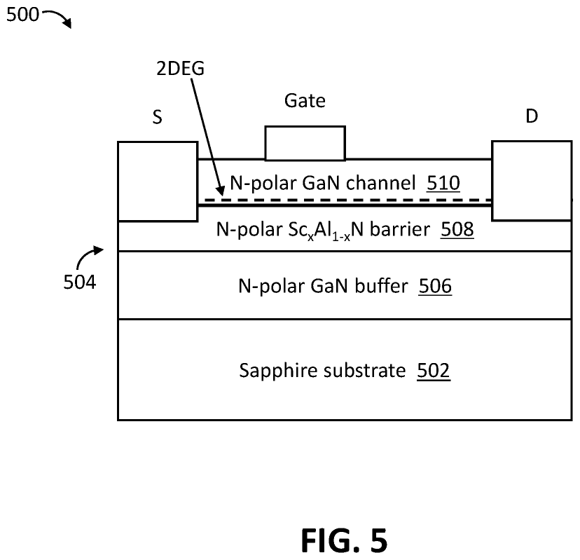

FIG. 5 depicts a device 500 having a layer of a scandium III-nitride material in accordance with one example. The device 500 may be fabricated via the method 400 of FIG. 4 and/or another method. In this example, the device 500 is configured as a HEMT device. In other cases, the device 500 is configured as a non-electronic device.

The device 500 includes a substrate 502 and a semiconductor heterostructure 504 supported by the substrate 502. The substrate 502 may be composed of, or otherwise include, sapphire, but alternative or additional materials may be used, including for instance, SiC. In the example of FIG. 5, the heterostructure 504 is in contact with the substrate 502.

In other cases, one or more layers are disposed between the substrate 502 and the heterostructure 504.

The device 500 includes a buffer or other semiconductor layer 506 of the heterostructure 504. The buffer layer 506 is supported by the substrate 502. In the example of FIG. 5, the buffer layer 506 is in contact with the substrate 502. The buffer layer 506 is composed of, or otherwise includes, a first III-nitride semiconductor material. In some cases, the first Ill-nitride semiconductor material is GaN, but other Ill-nitride materials may be used, including, for instance, AlN and alloys of AlN and GaN. The buffer layer 506 may be doped, unintentionally doped, or un-doped.

The device 500 includes a barrier or other semiconductor layer 508 of the heterostructure 504. The barrier layer 508 is supported by the buffer layer 506. In the example of FIG. 5, the barrier layer 508 is in contact with the buffer layer 506. The barrier layer 508 is composed of, or otherwise includes, a second III-nitride semiconductor material.

The second III-nitride semiconductor material may differ from the first III-nitride semiconductor material. The second III-nitride semiconductor material includes scandium, such as ScₓAl₁₋ₓN, as described herein. The scandium composition may fall within a range of about 0.11 to about 0.38.

The buffer and barrier layers 506, 508 may be lattice matched or lattice mismatched.

In the HEMT example of FIG. 5, the device 500 also includes a channel layer 510 supported by the barrier layer 508. The channel layer 510 may be in contact with the barrier layer 508. In other cases, one or more semiconductor layers may be disposed between the channel and barrier layers 508, 510. The channel layer 510 is composed of, or otherwise includes, a compound semiconductor material, such as a III-nitride semiconductor material, e.g., GaN, AlGaN, InGaN, or InN.

In some cases, the buffer and barrier layers 506, 508 are nitrogen-polar. In other cases, the buffer and barrier layers 506, 508 are metal-polar. In the latter cases, the III-nitride semiconductor materials of the buffer and barrier layers 506, 508 are lattice mismatched.

The heterostructure 504 may include one or more further semiconductor layers. For instance, the heterostructure 504 may include a semiconductor layer disposed between the buffer and barrier layers 506, 508. The further semiconductor layer may be composed of, or otherwise include, a third III-nitride semiconductor material (e.g., AlN) differing from the first Ill-nitride semiconductor material. The further semiconductor layer may be N-polar as well, insofar as the lattice polarity of the layers of the heterostructure 504 will follow the polarity of the initial buffer layer 506.

The epitaxy and characteristics of N-polar ScₓAl₁₋ₓN and other scandium Ill-nitride layers and the application thereof in HEMT and other structures and devices have been described above. For instance, the epitaxial growth (e.g., molecular beam epitaxy) of single-phase wurtzite N-polar ScₓAl₁₋ₓN (x falling in a range from about 0.11 to about 0.38) on sapphire substrates was attained by locking its lattice-polarity to an underlying N-polar GaN buffer. Coherent growth of lattice-matched Sc_{0.18}Al_{0.82}N on GaN has been confirmed by x-ray diffraction reciprocal space mapping of the asymmetric (105) plane, whereas lattice-mismatched, fully relaxed Sc_{0.11}Al_{0.89}N and Sc_{0.30}Al_{0.70}N epilayers exhibited crack-free surfaces. The on-axis N-polar crystallographic orientation is unambiguously confirmed by wet chemical etching. High electron mobility transistors using N-polar Sc_{0.18}Al_{0.82}N as barrier have been successfully grown on sapphire substrates, which present the existence of well confined two-dimensional electron gas. A Hall mobility of about 564 cm²/V·s is measured for a 15-nm-thick Sc_{0.18}Al_{0.52}N barrier sample with a sheet electron concentration of 4.1×10¹³ cm⁻², and the corresponding sheet resistance is as low as 271 Ω/sq. The polarity-controlled epitaxy of ScₓAl₁₋ₓN provides new opportunities for applications in high-frequency and high-power electronic and other (e.g., ferroelectric) devices.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a semiconductor heterostructure supported by the substrate, the semiconductor heterostructure comprising:
a first semiconductor layer supported by the substrate and comprising a first III-nitride semiconductor material; and
a second semiconductor layer supported by the first semiconductor layer and comprising a second III-nitride semiconductor material,
wherein:
the second III-nitride semiconductor material comprises scandium; and
the first and second semiconductor layers are nitrogen-polar.

2. The device of claim 1, wherein the first semiconductor layer comprises gallium nitride (GaN).

3. The device of claim 1, wherein the second semiconductor layer comprises scandium aluminum nitride (ScₓAl₁₋ₓN).

4. The device of claim 1, wherein the first semiconductor is in contact with the substrate.

5. The device of claim 1, wherein the second semiconductor layer is in contact with the first semiconductor layer.

6. The device of claim 1, further comprising a third semiconductor layer disposed between the first and second semiconductor layers, wherein the third semiconductor layer comprises a third III-nitride semiconductor material differing from the first Ill-nitride semiconductor material.

7. The device of claim 6, wherein the third semiconductor layer comprises aluminum nitride (AlN).

8. The device of claim 1, wherein the first and second semiconductor layers are lattice matched.

9. The device of claim 1, wherein the first and second semiconductor layers are lattice mismatched.

10. A transistor device comprising:
a substrate;
a buffer layer supported by the substrate and comprising a first III-nitride semiconductor material;
a barrier layer supported by the buffer layer and comprising a second III-nitride semiconductor material; and
a channel layer supported by the barrier layer and comprising a compound semiconductor material,
wherein:
the second Ill-nitride semiconductor material comprises scandium; and
the buffer and barrier layers are nitrogen-polar.

11. The transistor device of claim 10, wherein the first Ill-nitride semiconductor material and the second III-nitride semiconductor material are lattice mismatched.

12. The transistor device of claim 10, wherein the compound semiconductor material comprises the first Ill-nitride semiconductor material.

13. The transistor device of claim 10, wherein the buffer layer comprises gallium nitride (GaN).

14. The transistor device of claim 10, wherein the barrier layer comprises scandium aluminum nitride (ScₓAl₁₋ₓN).

15. The transistor device of claim 10, wherein the buffer layer is in contact with the substrate.

16. The transistor device of claim 10, further comprising a further semiconductor layer disposed between the buffer and barrier layers, wherein the further semiconductor layer comprises a third Ill-nitride semiconductor material differing from the first Ill-nitride semiconductor material.

17. The device of claim 16, wherein the further semiconductor layer comprises aluminum nitride (AlN).

18. A transistor device comprising:
a substrate;
a buffer layer supported by the substrate and comprising a first III-nitride semiconductor material;
a barrier layer supported by the buffer layer and comprising a second III-nitride semiconductor material; and
a channel layer supported by the barrier layer and comprising a compound semiconductor material,
wherein:
the second III-nitride semiconductor material comprises scandium; and
the first Ill-nitride semiconductor material and the second III-nitride semiconductor material are lattice mismatched.

19. A method of fabricating a heterostructure, the method comprising:
growing epitaxially a first semiconductor layer of the heterostructure, the first semiconductor layer comprising a first III-nitride semiconductor material, the first III-nitride semiconductor material being supported by a substrate; and
after growing the first semiconductor layer, growing epitaxially a second semiconductor layer of the heterostructure such that the second semiconductor layer is supported by the first semiconductor layer, the second semiconductor layer comprising a second III-nitride semiconductor material,
wherein:
the second III-nitride semiconductor material comprises scandium; and
the first and second semiconductor layers are nitrogen-polar.

20. The method of claim 19, wherein growing epitaxially the second semiconductor layer is implemented under nitrogen-rich conditions.

21. The method of claim 19, wherein growing epitaxially the second semiconductor layer is implemented at a growth temperature falling in a range from about 600 degrees Celsius to about 900 degrees Celsius.
